(19) United States
(12) Patent Application Publication
(10) Pub. No.: US 2015/0262635 A1
(43) Pub. Date: Sep. 17, 2015

(54) LATCH CIRCUIT AND SEMICONDUCTOR DEVICE INCLUDING THE SAME

(71) Applicant: SK hynix Inc., Gyeonggi-do (KR)

(72) Inventors: Min-Ho JOO, Gyeonggi-do (KR); Sung-Soo CHI, Gyeonggi-do (KR); Sung-Ho KIM, Gyeonggi-do (KR)

(21) Appl. No.: 14/556,917

(22) Filed: Dec. 1, 2014

(30) Foreign Application Priority Data
Mar. 13, 2014 (KR) 10-2014-0029643
Jun. 30, 2014 (KR) 10-2014-0080861

(51) Int. Cl. G11C 7/10; G11C 7/20; G11C 5/06; G11C 7/22

(52) U.S. Cl. CPC G11C 7/1087; G11C 7/22; G11C 7/20; G11C 5/06

(57) ABSTRACT

A latch circuit includes: first to N^{th} storage nodes, where N is an even number equal to or greater than 4; first to N^{th} pairs of transistors, each of which includes a PMOS transistor and an NMOS transistor coupled in series with each other through a corresponding storage node among the first to N^{th} storage nodes, wherein each of the first to N^{th} storage nodes is coupled with a gate of the NMOS transistor included in a previous one of the pairs of transistors and a gate of the PMOS transistor included in a next one of the pairs of transistors; and an initialization block suitable for initializing voltages of two or more nodes among the first to N^{th} storage nodes to a first level in response to an initialization signal.

### CROSS-REFERENCE TO RELATED APPLICATIONS

The present application claims priority of Korean Patent Application Nos. 10-2014-0029643 and 10-2014-0080861, filed on Mar. 13, 2014, and Jun. 30, 2014, respectively, which are incorporated herein by reference in their entirety.

### BACKGROUND

1. Field

Various exemplary embodiments of the present invention relate to a latch circuit and a semiconductor device including the same.

2. Description of the Related Art

FIG. 1 is a block diagram illustrating a memory device according to a prior art.

Referring to FIG. 1, the memory device includes a cell array 110 including a plurality of memory cells, a row circuit 120 for enabling a word line selected by a row address R_ADD, and a column circuit 130 for accessing a memory cell of a bit line selected by a column address C_ADD for read and write operations.

A row fuse circuit 140 stores a row address corresponding to a failed memory cell in the cell array 110 as a repair row address REPAIR_R_ADD. A row comparison block 150 compares the repair row address REPAIR_R_ADD stored in the row fuse circuit 140 with the row address R_ADD inputted from an exterior of the memory device. When the repair row address REPAIR_R_ADD and the row address R_ADD are the same as each other, the row comparison block 150 controls the row circuit 120 to enable a redundancy word line instead of a word line designated by the row address R_ADD.

A column fuse circuit 160 stores a column address corresponding to a failed memory cell in the cell array 110 as a repair column address REPAIR_C_ADD. A column comparison block 170 compares the repair column address REPAIR_C_ADD stored in the column fuse circuit 160 with the column address C_ADD inputted from an exterior of the memory device. When the repair column address REPAIR_C_ADD and the column address C_ADD are the same as each other, the column comparison block 170 controls the column circuit 130 to access a redundancy bit line instead of a bit line designated by the column address C_ADD.

Laser fuses are mainly used as fuse circuits 140 and 160. The laser fuse stores data of a logic high level or a logic low level based on whether the fuse is cut. The laser fuse is programmable in a wafer stage but it is not programmable after the wafer stage, such as in a package stage. Also, it is difficult to design laser fuses to occupy a small area due to pitch limitations.

To solve this problem, U.S. Pat. Nos. 6,904,751, 6,777,757, 6,667,902, 7,173,851 and 7,269,047 disclose a memory device including a non-volatile memory circuit such as an e-fuse array circuit, a NAND flash memory, a NOR flash memory, an Erasable Programmable Read Only Memory (EPROM), an Electrically Erasable Programmable Read Only Memory (EEPROM), a Ferroelectric Random Access Memory (FRAM) and a Magnetoresistive Random Access Memory (MRAM), and using the non-volatile memory circuit to store repair information.

FIG. 2 is a block diagram illustrating a memory device using a non-volatile memory circuit to store repair information according to a prior art.

Referring to FIG. 2, the memory device includes a plurality of memory banks BK0 to BK3, latch sets 210_0 to 210_3 provided for the memory banks BK0 to BK3 to store repair information, respectively, a latch set 210_4 for storing setting information, a setting circuit 220, and a non-volatile memory circuit 201.

The non-volatile memory circuit 201 is a substitute for the fuse circuits 140 and 160. Repair information corresponding to all the banks BK0 to BK3, i.e., repair addresses, is stored in the non-volatile memory circuit 201. Also, setting information required for an operation of the memory device is stored in the non-volatile memory circuit 201. The non-volatile memory circuit 201 may be one among an e-fuse array circuit, a NAND flash memory, a NOR flash memory, an Erasable Programmable Read Only Memory (EPROM), an Electrically Erasable Programmable Read Only Memory (EEPROM), a Ferroelectric Random Access Memory (FRAM) and a Magnetoresistive Random Access Memory (MRAM).

The latch sets 210_0 to 210_3 store repair information of the memory banks thereof, respectively. For example, the latch set 210_0 stores the repair information of the memory bank BK0, and the latch set 210_2 stores the repair information of the memory bank BK2. The latch set 210_4 stores setting information used for the setting circuit 220. The setting circuit 220 may set various setting values required for an operation of the memory device, e.g., a level of an internal voltage, diverse types of latency and so on. The latch sets 210_0 to 210_4 may store the repair information while a power source is provided. The repair information to be stored in the latch sets 210_0 to 210_4 is transmitted from the non-volatile memory circuit 201. The non-volatile memory circuit 201 transmits the stored repair information to the latch sets 210_0 to 210_3 when a boot-up signal BOOTUP is enabled.

Since the non-volatile memory circuit 201 is formed in an array, it takes a predetermined time to load the data stored therein, and thus it is impossible to perform a repair operation through prompt loading of the data stored in the non-volatile memory circuit 201. Therefore, the repair information and the setting information stored in the non-volatile memory circuit 201 are transmitted to and stored in the latch sets 210_0 to 210_4, and the data stored in the latch sets 210_0 to 210_4 are used for the repair operation of the memory banks BK0 to BK3 and the setting operation of the setting circuit 220. The process of transmitting the repair information and the setting information from the non-volatile memory circuit 201 to the latch sets 210_0 to 210_4 is referred to as a boot-up operation. When the boot-up operation is completed, the memory device may repair a failed cell and perform various setting operations, and subsequently it may begin to perform a normal operation.

When a scheme for storing the repair information and the setting information through the non-volatile memory circuit 201 is applied as described with reference to FIG. 2, a great deal of the latch sets 210_0 to 210_4 are used. However, the use of many latch sets 210_0 to 210_4 raises the possibility of a malfunction caused by a soft error. In a soft error, data stored in a latch is corrupted by cosmic rays such as alpha particles.

### SUMMARY

Various exemplary embodiments of the present invention are directed to a latch circuit and a semiconductor device that is resistant to soft errors.

In accordance with an embodiment of the present invention, a latch circuit includes: first to N^{th} storage nodes, where N is an even number equal to or greater than 4; first to N^{th} pairs of transistors, each of which includes a PMOS transistor and an NMOS transistor coupled in series with each other through a corresponding storage node among the first to N^{th} storage nodes, wherein each of the first to N^{th} storage nodes is coupled with a gate of the NMOS transistor included in a previous one of the pairs of transistors and a gate of the PMOS transistor included in a next one of the pairs of transistors; and an initialization block suitable for initializing voltages of two or more nodes among the first to N^{th} storage nodes to a first level in response to an initialization signal.

The initialization block may initialize odd-numbered ones among the first to N^{th} storage nodes to the first level in response to the initialization signal. Also, the initialization block may also initialize even-numbered ones among the first to N^{th} storage nodes to the first level in response to the initialization signal d.

The latch circuit may further include a data input control block suitable for transmitting data of a data input line to two or more nodes among the first to N^{th} storage nodes in response to a selection signal.

In accordance with another embodiment of the present invention, a semiconductor device includes: a non-volatile memory circuit; a data bus suitable for transmitting data outputted from the non-volatile memory circuit; a selection signal generation block suitable for generating a plurality of selection signals; and a plurality of latch sets, each of which is enabled in response to a corresponding one among the selection signals and stores the data transmitted through the data bus, and includes a plurality of latch circuits, wherein each of the latch circuits includes: first to N^{th} storage nodes, where N is an even number equal to or greater than 4; first to N^{th} pairs of transistors, each of which includes a PMOS transistor and an NMOS transistor coupled in series with each other through a corresponding storage node among the first to N^{th} storage nodes, wherein each of the first to N^{th} storage nodes is coupled with a gate of the NMOS transistor included in a previous one of the pairs of transistors and a gate of the PMOS transistor included in a next one of the pairs of transistors; an initialization block suitable for initializing voltages of two or more nodes among the first to N^{th} storage nodes to a first level in response to an initialization signal; and a data input control block suitable for transmitting data of a corresponding line among lines forming the data bus to two or more nodes among the first to N^{th} storage nodes in response to a corresponding selection signal among the selection signals.

The semiconductor device may be a memory device suitable for performing a repair operation to a failed memory cell included therein by using the data stored in the latch sets, and the non-volatile memory circuit may store repair data for the repair operation.

In accordance with another embodiment of the present invention, a latch circuit includes: a first inverter including a first storage node as an input node and a second storage node as an output node; a second inverter including the second storage node as an input node and the first storage node as an output node; a first transistor coupled with the first storage node at its drain and source, and coupled with the second storage node at its gate; a second transistor coupled with the second storage node at its drain and source, and coupled with the first storage node at its gate.

The first transistor and the second transistor may be PMOS transistors.

In accordance with another embodiment of the present invention, a semiconductor device includes: a non-volatile memory circuit; a data bus suitable for transmitting data outputted from the non-volatile memory circuit; a selection signal generation block suitable for generating a plurality of selection signals; and a plurality of latch sets, each of which is enabled in response to a corresponding one among the selection signals and stores the data transmitted through the data bus, and includes a plurality of latch circuits, wherein each of the latch circuits includes: a first inverter including a first storage node as an input node and a second storage node as an output node; a second inverter including the second storage node as an input node and the first storage node as an output node; a first transistor coupled with the first storage node at its drain and source, and coupled with the second storage node at its gate; a second transistor coupled with the second storage node at its drain and source, and coupled with the first storage node at its gate; a data input control block suitable for transferring data from the data bus to one or more among the first and second storage nodes in response to a corresponding one among the selection signals.

In accordance with another embodiment of the present invention, a latch circuit includes: a first PMOS transistor including a source coupled with a power source voltage node, a drain coupled with a first storage node, and a gate coupled with a fourth storage node; a first NMOS transistor including a drain coupled with the first storage node, a source coupled with a ground voltage node, and a gate coupled with a second storage node; a second PMOS transistor including a source coupled with the power source voltage node, a drain coupled with a second storage node, and a gate coupled with a first storage node; a second NMOS transistor including a drain coupled with the second storage node, a source coupled with the ground voltage node, and a gate coupled with a third storage node; a third PMOS transistor including a source coupled with the power source voltage node, a drain coupled with a third storage node, and a gate coupled with the second storage node; a third NMOS transistor including a drain coupled with the third storage node, a source coupled with the ground voltage node, and a gate coupled with the fourth storage node; a fourth PMOS transistor including a source coupled with the power source voltage node, a drain coupled with the fourth storage node, and a gate coupled with the third storage node; a fourth NMOS transistor including a drain coupled with the fourth storage node, and a source coupled with the ground voltage node, and a gate coupled with the first storage node; a fifth PMOS transistor suitable for initializing the fourth storage node to a first level in response to an initialization signal; a sixth PMOS transistor suitable for initializing the second storage node to the first level in response to the initialization signal; a fifth NMOS transistor suitable for transmitting data of an inverted data input line to the second storage node in response to a selection signal; a sixth NMOS transistor suitable for transmitting data of a data input line to the third storage node in response to the selection signal; a seventh NMOS transistor suitable for transmitting the data of the inverted data input line to the fourth storage node in response to the selection signal; and an eighth NMOS transistor suitable for transmitting the data of the data input line to the first storage node in response to the selection signal.

The first to eighth NMOS transistors may be arranged in order of the fourth NMOS transistor, the seventh NMOS transistor, the fifth NMOS transistor, the second NMOS transistor, the third NMOS transistor, the sixth NMOS transistor, the eighth NMOS transistor and the first NMOS transistor, in a first direction in a first active region stretched in the first direction.

The second to sixth PMOS transistors may be arranged in order of the fourth PMOS transistor, the fifth PMOS transistor, the sixth PMOS transistor, the second PMOS transistor and the third PMOS transistor, in the first direction in a second active region stretched in the first direction.

The latch circuit may further include an inverter including the data input line as an input line and the inverted data input line as an output line, and the inverter may include a seventh PMOS transistor and a ninth NMOS transistor. The first PMOS transistor and the seventh PMOS transistor may be arranged in order of the first PMOS transistor and the seventh PMOS transistor, in the first direction in a third active region stretched in the first direction.

### BRIEF DESCRIPTION OF THE DRAWINGS

FIG. 1 is a block diagram illustrating a memory device according to a prior art.

FIG. 2 is a block diagram illustrating a memory device using a non-volatile memory circuit to store repair information according to a prior art.

FIG. 3 is a block diagram illustrating a semiconductor device in accordance with an embodiment of the present invention.

FIG. 4 is a circuit diagram exemplarily illustrating a flip-flop circuit shown in FIG. 3.

FIG. 5 is a block diagram exemplarily illustrating a latch set shown in FIG. 3.

FIG. 6 is a circuit diagram exemplarily illustrating a latch circuit shown in FIG. 5.

FIG. 7 is a circuit diagram exemplarily illustrating a latch circuit shown in FIG. 5.

FIG. 8 is a timing diagram illustrating a boot-up operation of a semiconductor device in accordance with an embodiment of the present invention.

FIG. 9 is a block diagram illustrating a memory device in accordance with another embodiment of the present invention.

FIG. 10 is a layout diagram illustrating transistors that form an embodiment of the latch circuit shown in FIG. 6.

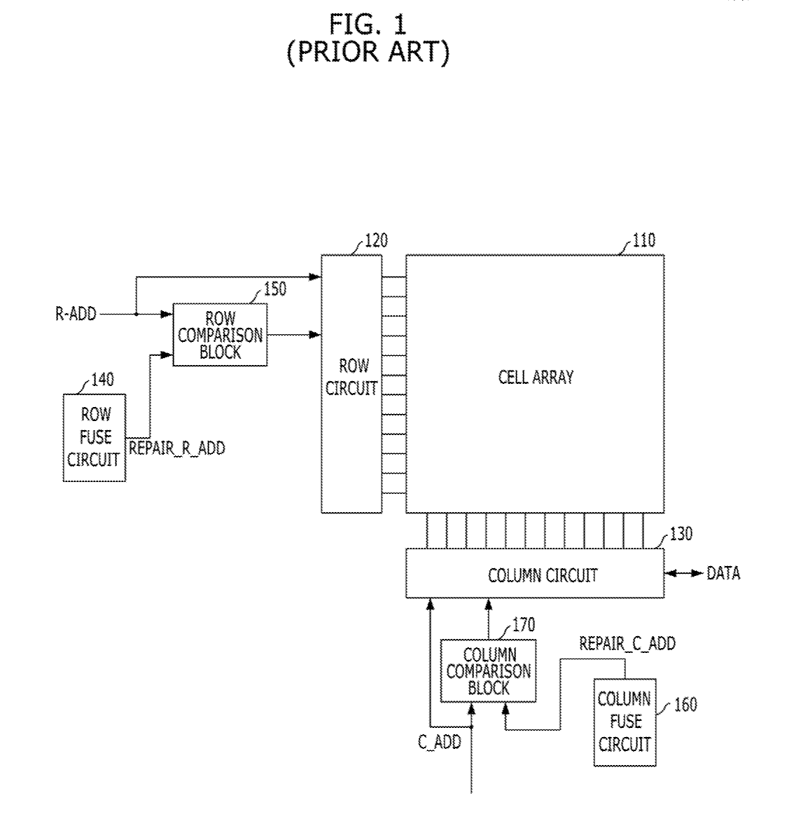

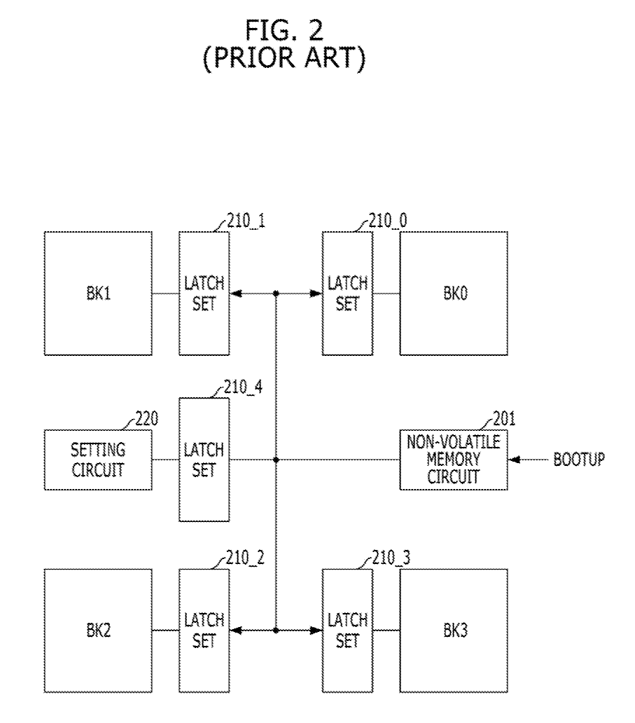

### DETAILED DESCRIPTION

Exemplary embodiments of the present invention are described below in more detail with reference to the accompanying drawings. These embodiments are provided so that this disclosure is thorough and complete, and fully conveys the scope of the present invention to those skilled in the art. All “embodiments” referred to in this disclosure refer to embodiments of the inventive concept disclosed herein. The embodiments presented are merely examples and are not intended to limit the inventive concept.

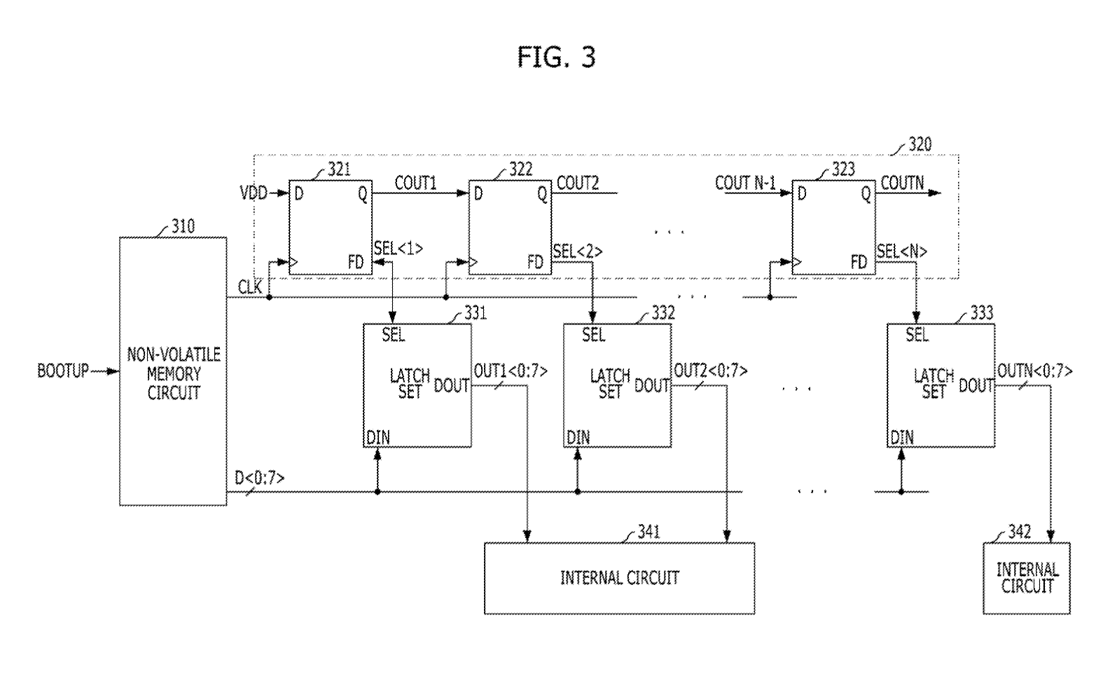

FIG. 3 is a block diagram illustrating a semiconductor device in accordance with an embodiment of the present invention.

The semiconductor device may be one among a memory device, a CPU and diverse types of integrated circuit chips such as various control chips.

Referring to FIG. 3, the semiconductor device may include a non-volatile memory circuit 310, a data bus D<0:7>, a selection signal generation block 320, latch sets 331 to 333, and internal circuits 341 and 342.

Information for the internal circuits 341 and 342 may be stored in the non-volatile memory circuit 310. The non-volatile memory circuit 310 may sequentially output all the stored data to the data bus D<0:7> in response to a boot-up signal BOOTUP. A clock CLK outputted from the non-volatile memory circuit 310 may be synchronized with the data transmitted through the data bus D<0:7>. The non-volatile memory circuit 310 may be one among an e-fuse array circuit, a NAND flash memory, a NOR flash memory, an Erasable Programmable Read Only Memory (EPROM), an Electrically Erasable Programmable Read Only Memory (EEPROM), a Ferroelectric Random Access Memory (FRAM) and a Magnetoresistive Random Access Memory (MRAM).

The selection signal generation block 320 may generate a plurality of selection signals SEL<1:N>. The selection signal generation block 320 may sequentially enable the selection signals SEL<1:N> whenever the clock CLK is enabled. For example, when a selection signal SEL<X>, where X is an Integer equal to or more than 1 and less than N, is enabled in response to the current enablement of the clock CLK, a selection signal SEL<X+1> may be enabled in response to the next enablement of the clock CLK. The selection signal generation block 320 may include N number of flip-flop circuits 321 to 323. Each of the flip-flop circuits 321 to 323 may shift a signal inputted to a D node thereof by a one-clock period in synchronization with the clock CLK, and output the shifted signal through a Q node thereof. The flip-flop circuits 321 to 323 may generate the selection signals SEL<1:N> based on the signals inputted to the D node thereof, and output the selection signals SEL<1:N> through FD nodes thereof, respectively. The flip-flop circuits 321 to 323 may be coupled in series with each other. In other words, an output signal Q of the current flip-flop circuit may be an input signal D of the next flip-flop circuit. The first flip-flop circuit 321 among the flip-flop circuits 321 to 323 may receive a power source voltage VDD as an input signal. Internal structures and operations of the flip-flop circuits 321 to 323 are described in detail below with reference to the drawing.

The latch sets 331 to 333 may receive and store the data transferred through the data bus D<0:7> when a corresponding selection signal among the selection signals SEL<1:N> is enabled. Each of the latch sets 331 to 333 may include as many latch circuits as the bit-width of the data bus D<0:7> in order to store data with the bit-width of the data bus D<0:7>. For example, each of the latch sets 331 to 333 may include eight of the latch circuits for an eight-bit data bus D<0:7>. The latch sets 331 to 333 may provide the stored data to the internal circuits 341 and 342 through data output lines OUT1<0:7> to OUTN<0:7>, respectively. The latch sets 331 to 333 may share the data bus D<0:7> transferring the data for each of the latch sets 331 to 333 while each of the latch sets 331 to 333 may have a dedicated one among the data output lines OUT1<0:7> to OUTN<0:7>, through which the corresponding one of the latch sets 331 to 333 outputs the stored data. Internal structures and operations of the latch sets 331 to 333 are described in detail below with reference to the drawings.

The internal circuits 341 and 342 may use the information stored in the latch sets 331 to 333. For example, the internal circuit 341 may set internal voltage values for the semiconductor device based on the information stored in the latch sets 331 and 332, and the internal circuit 342 may repair a failure of the semiconductor device based on the information stored in the latch set 333.

In the embodiment of FIG. 3, the selection signals SEL<1:N> are generated by the selection signal generation block 320 using the clock CLK, and the data of the data bus D<0:7> are stored in the latch sets 331 to 333 corresponding to the enabled selection signal during the boot-up operation where the data of the non-volatile memory circuit 310 are transmitted to the latch sets 331 to 333. In other words, a simple scheme for selecting one of the latch sets 331 to 333 to store the data outputted from the non-volatile memory circuit 310 is adopted, and consequently the number of lines between the non-volatile memory circuit 310 and the latch sets 331 to 333 as well as the time required for a boot-up operation may be minimized.

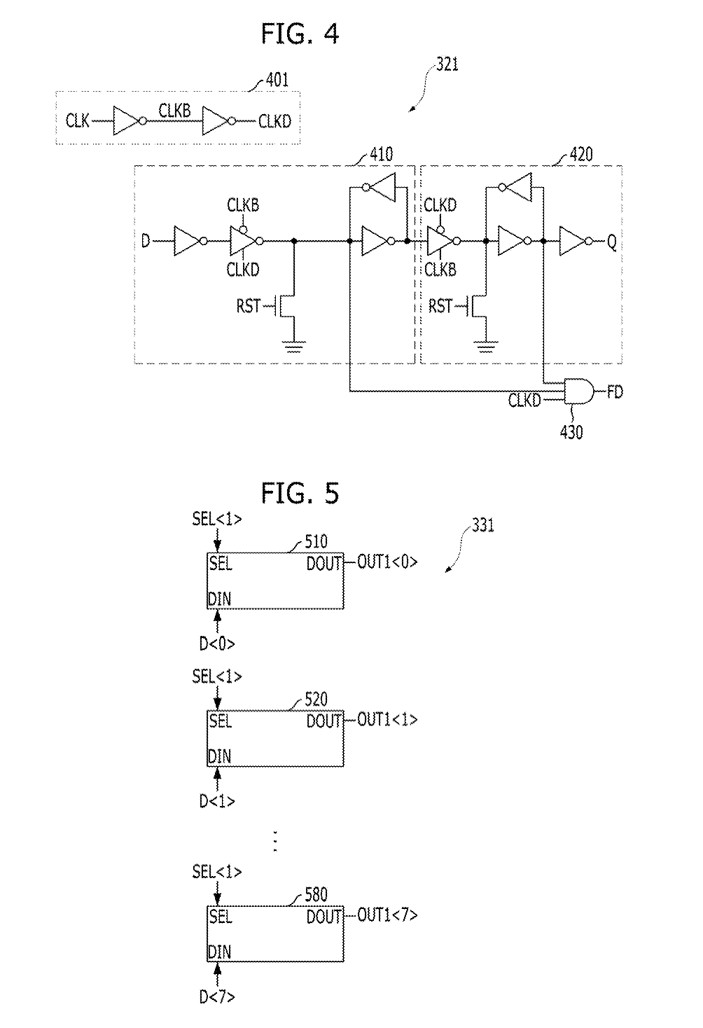

FIG. 4 is a circuit diagram exemplarily illustrating the flip-flop circuit 321 shown in FIG. 3. Each of the other flip-flop circuits 322 and 323 shown in FIG. 3 may be the same as the flip-flop circuit 321 shown in FIG. 4.

Referring to FIG. 4, the flip-flop circuit 321 may include a clock input unit 401, a first stage 410, a second stage 420, and a selection signal generation unit 430.

The clock input unit 401 may buffer the clock CLK inputted to a clock node of the flip-flop circuit 321. An inverted clock CLKB may have a phase opposite to the clock CLK, and a clock CLKD may be the clock CLK, which is buffered by the clock input unit 401.

The first stage 410 may receive and store a signal inputted to the D node when the clock CLKD has a first level, e.g., a logic high level. When an initialization signal RST is enabled to a logic high level, the signal stored in the first stage 410 may be initialized.

The second stage 420 may receive and store the signal stored in the first stage 410 when the clock CLKD has a second level, e.g., a logic low level. When the initialization signal RST is enabled to a logic high level, the signal stored in the second stage 420 may be initialized.

The selection signal generation unit 430 may generate a selection signal FD, which may correspond to one of the selection signals SEL<1:N>, for example the selection signal SEL<1> for the flip-flop circuit 321, based on the signals stored in the first stage 410 and the second stage 420 and the signals and the clock CLKD. The selection signal FD may be enabled before the signal inputted to the first stage 410 is transmitted to the second stage 420.

FIG. 5 is a block diagram exemplarily illustrating the latch set 331 shown in FIG. 3. Each of the other latch sets 332 and 333 shown in FIG. 3 may be the same as the latch set 331 shown in FIG. 5.

Referring to FIG. 5, the latch set 331 may include 8 latch circuits 510 to 580 corresponding to the bit-width of the data bus D<0:7>. The same signal may be inputted to each SEL node of the latch circuits 510 to 580. Each of the latch circuits 510 to 580 may receive and output corresponding data transferred from the data bus D<0:7> through DIN and DOUT nodes thereof. In other words, the latch circuits 510 to 580 inside the same latch set 331 may share the selection signal SEL<1> with each other while they may receive different data loaded on the data bus D<0:7> and have different outcomes.

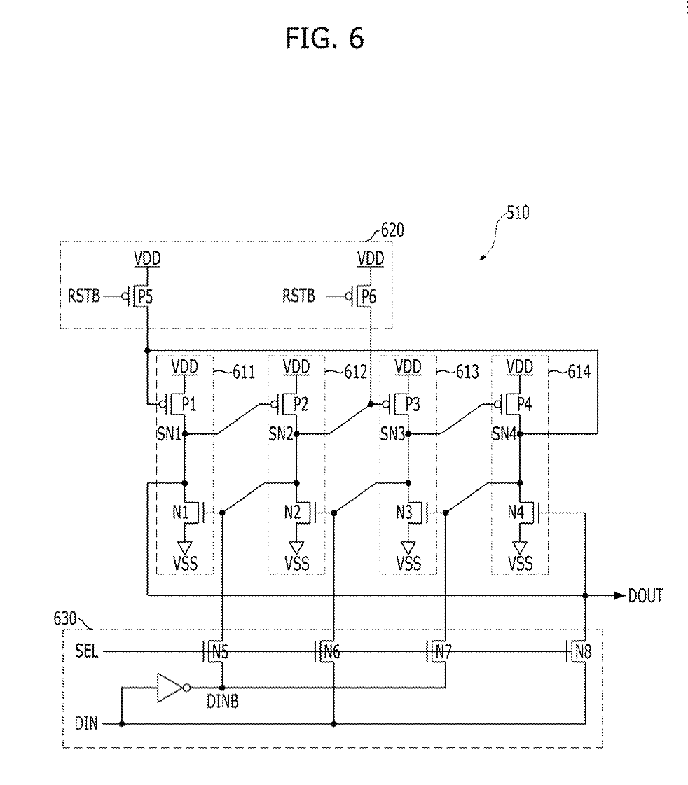

FIG. 6 is a circuit diagram exemplarily illustrating the latch circuit 510 shown in FIG. 5. Each of the other latch circuits 520 to 580 may be the same as the latch circuit 510 shown in FIG. 6.

Referring to FIG. 6, the latch circuit 510 may include first to fourth storage nodes SN1 to SN4, a plurality of pairs of first to fourth transistors 611 to 614, an initialization unit 620, and a data input control unit 630.

The pairs of the first to fourth transistors 611 to 614 may include PMOS transistors P1 to P4 and NMOS transistors N1 to N4 which are coupled in series with each other at corresponding storage nodes SN1 to SN4, respectively. Gates of the NMOS transistor of the previous one of the pairs of the first to fourth transistors 611 to 614 and the PMOS transistor of the next one of the pairs of the first to fourth transistors 611 to 614 may be coupled at one of the storage nodes SN1 to SN4 included in the current one of the pairs of the first to fourth transistors 611 to 614. For example, the gates of the NMOS transistor N1 of the first pair of transistors 611 and the PMOS transistor P3 of the third pair of transistors 613 may be coupled at the second storage node SN2. The next one of the last pair of transistors 614 may be the first pair of transistors 611. Similarly, the previous one of the first pair of transistors 611 may be the last pair of transistors 614.

The initialization unit 620 may initialize voltages of two or more nodes among the storage nodes SN1 to SN4 in response to an initialization signal RSTB which is an inverted signal of the initialization signal RST. Since the stored data may change when the voltages of two or more nodes among the storage nodes SN1 to SN4 simultaneously change due to the characteristics of the latch circuit 510, the initialization unit 620 may initialize the latch circuit 510 by simultaneously applying a voltage to two or more nodes among the storage nodes SN1 to SN4, preferably two or more even-numbered nodes or two or more odd-numbered nodes. Although it is illustrated in the drawing that the initialization unit 620 initializes a value stored in the latch circuit 510 by applying a power source voltage VDD to the even-numbered storage nodes SN2 and SN4 when the initialization signal RSTB is enabled, the initialization unit 620 may initialize the latch circuit 510 in various ways. For example, the initialization unit 620 may initialize the value stored in the latch circuit 510 by applying a ground voltage VSS to the even-numbered storage nodes SN2 and SN4, or to the odd-numbered storage nodes SN1 and SN3, or it may initialize the value stored in the latch circuit 510 by applying the power source voltage VDD to the odd-numbered storage nodes SN1 and SN3. The initialization unit 620 may include two PMOS transistors P5 and P6 as shown in FIG. 6.

The data input control unit 630 may transmit data of the data input line DIN to the storage nodes SN1 to SN4 when the selection signal SEL is enabled. The data input control unit 630 may transmit the data of the data input line DIN to the odd-numbered storage nodes SN1 and SN3, and invert and transmit the data of the data input line DIN to the even-numbered storage nodes SN2 and SN4. This is because the polarities of the odd-numbered storage nodes SN1 and SN3 and the even-numbered storage nodes SN2 and SN4 are opposite to each other. It is exemplarily shown that the data input control unit 630 transmits the data of the data input line DIN to the storage nodes SN1 to SN4 when the selection signal SEL is enabled, which may vary. As another example, the data input control unit 630 may transmit the data of the data input line DIN to two or more nodes among the storage nodes SN1 to SN4, preferably two or more even-numbered nodes or two or more odd-numbered nodes. The data input control unit 630 may include four NMOS transistors N5 to N8 as shown in FIG. 6.

The data of the storage node SN1 among the storage nodes SN1 to SN4 may be provided to the output DOUT of the latch circuit 510. Although it is exemplarily described in the embodiment that the data of the storage node SN1 is provided to the output DOUT of the latch circuit 510, it is obvious that the data of any node among the storage nodes SN1 to SN4 may be provided to the output DOUT of the latch circuit 510.

The latch circuit 510 shown in FIG. 6 is resistant to soft errors caused by cosmic rays. Only when the data of two or more nodes among the storage nodes SN1 to SN4 simultaneously change due to cosmic rays may the data stored in the latch circuit 510 be corrupted by an error caused by cosmic rays. For example, although the data of the first storage node SN1 changes from 1 to 0 due to the cosmic rays when the data set to ‘1, 0, 1, 0’ is stored in the storage nodes SN1 to SN4, the data of the first storage node SN1 may change from 0 to 1 due to the PMOS transistor P1. In other words, a soft error does not occur unless the data of two or more storage nodes simultaneously change due to the cosmic rays in the latch circuit 510. The probability of the simultaneous data change of two or more storage nodes due to cosmic rays is extremely low.

Although it is exemplarily described in the embodiment of FIG. 6 that the latch circuit 510 includes four pairs of transistors 611 to 614 and four storage nodes SN1 to SN4, the latch circuit 510 may include N number of pairs of transistors and N number of storage nodes, where N is an even number greater than 4. For example, the latch circuit 510 may include 6 pairs of transistors and 6 storage nodes.

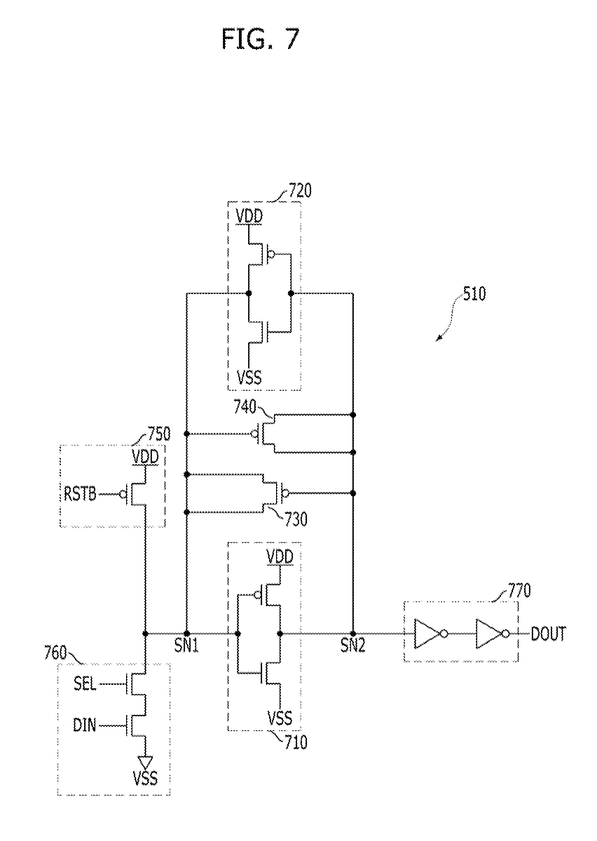

FIG. 7 is a circuit diagram exemplarily illustrating the latch circuit 510 shown in FIG. 5. Each of the other latch circuits 520 to 580 inside the latch set 331 may be as the same as the latch circuit 510 shown in FIG. 7.

Referring to FIG. 7, the latch circuit 510 may include a first inverter 710, a second inverter 720, a first transistor 730, and a second transistor 740. The latch circuit 510 may further include an initialization unit 750, a data input control unit 760 and a data output unit 770.

The first inverter 710 may receive the voltage of the first storage node SN1 as an input signal, and output the voltage of the second storage node SN2 as an output signal. The second inverter 720 may receive the voltage of the second storage node SN2 as an input signal, and output the voltage of the first storage node SN1 as an output signal. The first and second inverters 710 and 720 may store data corresponding to the voltage levels of the first and second storage nodes SN1 and SN2.

The first transistor 730 may be coupled with the first storage node SN1 at its drain and source, and coupled with the second storage node SN2 at its gate. The second transistor 740 may be coupled with the second storage node SN2 at its drain and source, and coupled with the first storage node SN1 at its gate. The first and second transistors 730 and 740 may prevent corruption of the data stored in the storage nodes SN1 and SN2 due to cosmic rays by increasing capacitances at the storage nodes SN1 and SN2. In other words, the first and second transistors 730 and 740 may prevent the occurrence of soft errors caused by cosmic rays. While the first and second transistors 730 and 740 may be NMOS transistors, preferably the first and second transistors 730 and 740 may be PMOS transistors where the rate of movement of carriers is slower than in NMOS transistors.

The initialization unit 750 may initialize a voltage of the first storage node SN1 in response to the initialization signal RSTB. Although it is exemplarily described in the embodiment that the initialization unit 750 initializes the voltage of the first storage node SN1, the initialization unit 750 may initialize a voltage of the second storage node SN2.

The data input control unit 760 may transmit the data of the data input line DIN to the first storage node SN1 when the selection signal SEL is enabled. When the data of the data input line DIN is set to ‘0’, a level of the first storage node SN1 may be maintained at an initialization level of ‘1’, and when the data of the data input line DIN is set to ‘1’, the level of the first storage node SN1 may change from the initialization level of ‘1’ to ‘0’. Although it is exemplarily described in the embodiment that the data input control unit 760 transmits the data of the data input line DIN to the first storage node SN1, the data input control unit 760 may transmit the data to the second storage node SN2.

The data output unit 770 may output the data stored in the second storage node SN2 through the output DOUT of the latch circuit 510. Although it is exemplarily described in the embodiment that the data output unit 770 outputs the data stored in the second storage node SN2, the data output unit 770 may output the data stored in the first storage node SN1.

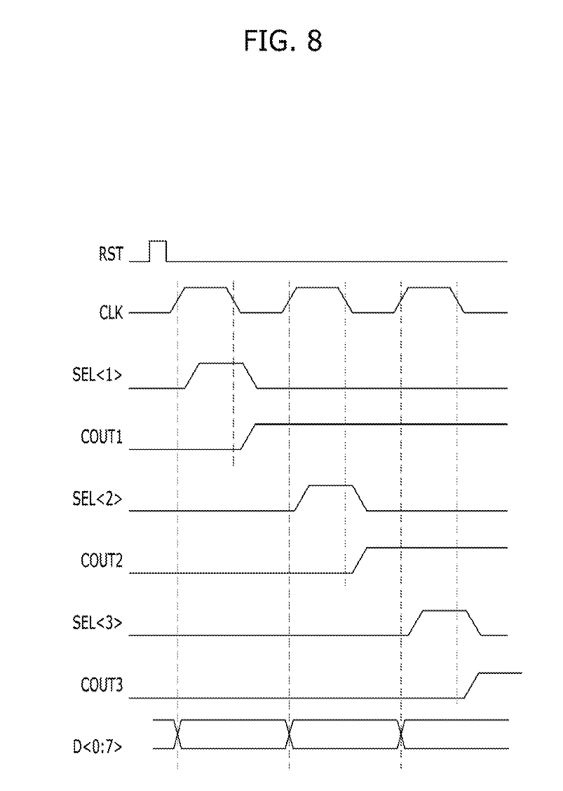

FIG. 8 is a timing diagram illustrating a boot-up operation of the semiconductor device in accordance with an embodiment of the present invention.

Referring to FIGS. 3, 4 and 8, the initialization signal RST may be enabled to ‘1’ while the initialization signal RSTB is enabled to ‘0’, and the flip-flop circuits 321 to 323 of the selection signal generation block 320 may be initialized, and the latch circuits 510 to 580 of each of the latch sets 331 to 333 may be initialized.

After the initialization operation, the flip-flop circuit 321 of the selection signal generation block 320 may enable the selection signal SEL<1> in response to a first enablement of the clock CLK. The flip-flop circuit 322 may enable the selection signal SEL<2> in response to a second enablement of the clock CLK. Similarly, the rest of the selection signals SEL<3:N> may be sequentially enabled whenever the clock CLK is enabled. When the selection signal SEL<1> is enabled, the data loaded on the data bus D<0:7> may be inputted to and stored in the latch circuits 510 to 580 of the latch set 331. Also, when the selection signal SEL<2> is enabled, the data loaded on the data bus D<0:7> may be inputted to and stored in the latch circuits 510 to 580 of the latch set 332. Through these processes, the data outputted from the non-volatile memory circuit 310, i.e., the data loaded on the data bus D<0:7>, may be sequentially transmitted to and stored in the latch sets 331 to 333.

After the boot-up operation is completed, the data stored in the latch sets 331 to 333 may be used by the internal circuits 341 and 342.

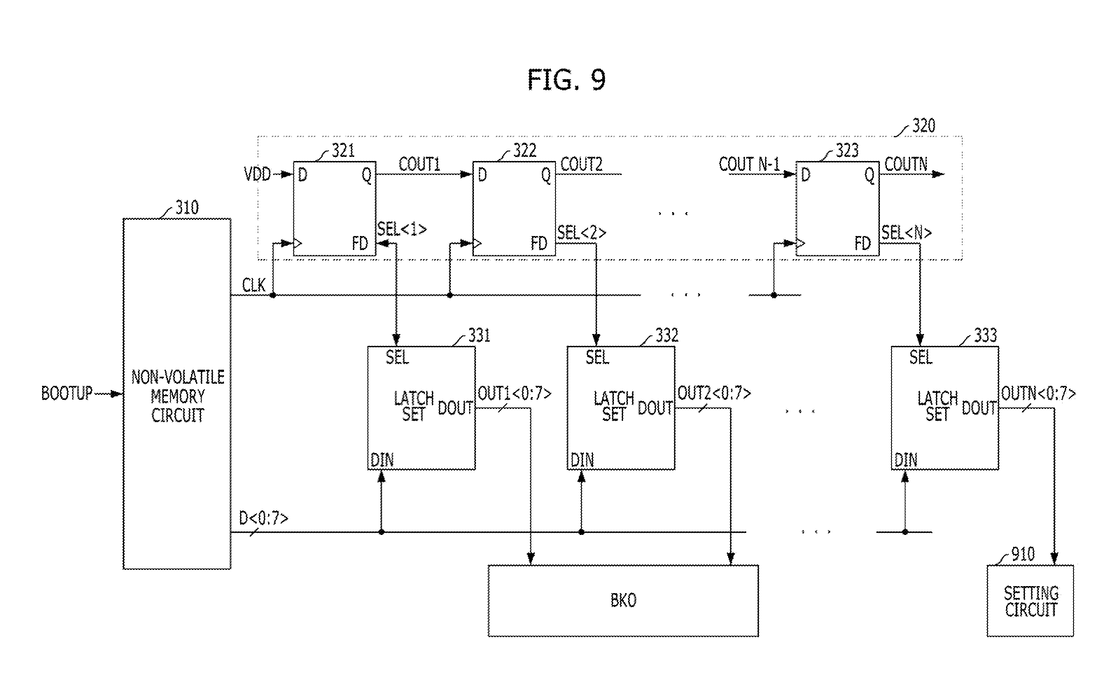

FIG. 9 is a block diagram illustrating a memory device in accordance with another embodiment of the present invention. FIG. 9 illustrates a memory device that incorporates an embodiment of the semiconductor device shown in FIG. 3.

Referring to FIG. 9, the memory device may include a non-volatile memory circuit 310, a data bus D<0:7>, a selection signal generation block 320, latch sets 331 to 333, a memory bank BK0, and a setting circuit 910.

The memory bank BK0 may include a cell array and circuits for read and/or write operations on the cell array. The memory bank BK0 may perform a repair operation for substituting a failed memory cell inside the cell array with a redundancy memory cell based on information outputted from the latch sets 331 and 332. Although one memory bank BK0 is illustrated in FIG. 9, it is obvious that a plurality of memory banks may be included in the memory device. For example, when the number of the latch sets 331 to 333 is 1280 (N=1280) and four (4) memory banks are included in the memory device, five (5) groups of 256 latch sets may be provided, four (4) of the memory banks may individually perform a repair operation based on information stored in 4 groups of 256 latch sets, and the setting circuit 910 may perform a setting operation based on the information stored in single group of 256 latch sets.

The setting circuit 910 may perform a setting operation required for an operation of the memory device based on the information outputted from the latch set 333. For example, the setting circuit 910 may set levels of diverse internal voltages such as a core voltage and a ground voltage used inside the memory device, and diverse parameter values such as latency of the memory device. It is obvious that the number of the latch set 333 that the setting circuit 910 uses may change according to the type of setting operations that the setting circuit 910 performs.

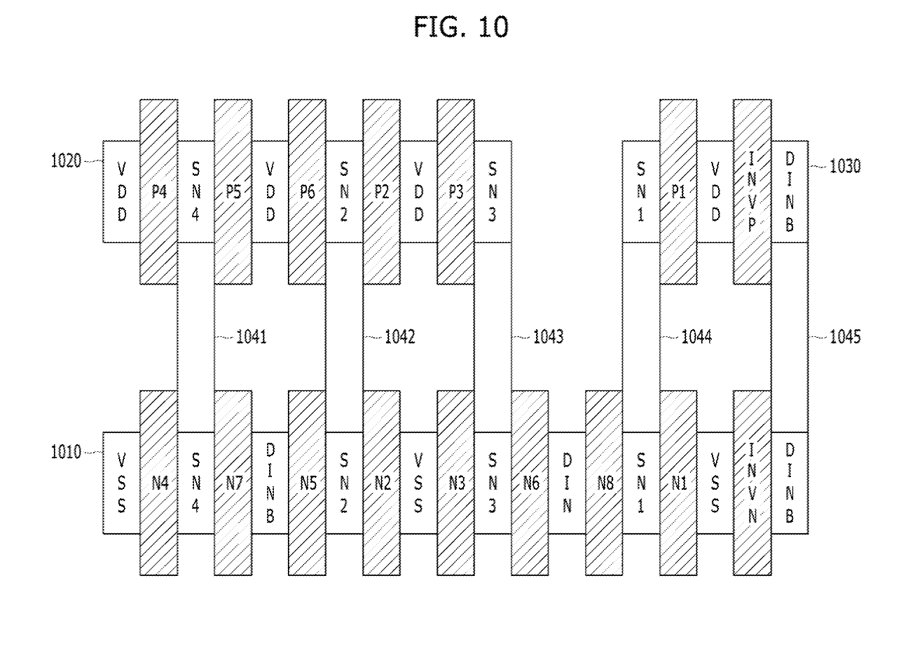

FIG. 10 is a layout diagram illustrating transistors formed of the latch circuit 510 shown in FIG. 6. In FIG. 10, gates of the transistors are represented by reference numerals shown in FIGS. 3 to 9. For example, P1 shown in FIG. 10 indicates a gate of the PMOS transistor P1 shown in FIG. 6. Also, FIG. 10 shows voltage levels applied to the drain and source of the transistors, or the node names of the transistors at the corresponding nodes.

Referring to FIG. 10, NMOS transistors N1 to N8 and INVN of the latch circuit 510 shown in FIG. 6 may be formed in a first active region 1010 stretched in a first direction or the X direction. The NMOS transistors may be arranged in order of N4, N7, N5, N2, N3, N6, N8, N1 and INVN in the X direction. The INVN is an NMOS transistor, among a PMOS transistor and an NMOS transistor forming the inverter, an input of which is the data input line DIN and an output of which is the inverted data input line DINB in the data input control unit 630. Since the NMOS transistors are formed in the first active region 1010, a conductive well corresponding to the first active region 1010 may be P-type well.

PMOS transistors P2 to N6 of the latch circuit 510 shown in FIG. 6 may be formed in a second active region 1020 stretched in the X direction. The PMOS transistors may be arranged in order of P4, P5, P6, P2 and P3 in the X direction. Since the PMOS transistors are formed in the second active region 1020, the conductive well corresponding to the second active region 1020 may be an N type well.

The PMOS transistor P4 and the NMOS transistor N4 may be aligned in a Y direction, and the PMOS transistor P2 and the NMOS transistor N2 may be aligned in the Y direction, and the PMOS transistor P3 and the NMOS transistor N3 may be aligned in the Y direction. The first active region 1010 and the second active region 1020 may be coupled with each other by metal lines 1041, 1042 and 1043 formed in the Y direction to form the second to fourth storage nodes SN2 to SN4.

PMOS transistors P1 and INVP of the latch circuit 510 shown in FIG. 6 may be formed in a third active region 1030 stretched in the X direction. The PMOS transistors may be arranged in order of P1 and INVP in the X direction. The INVP is a PMOS transistor, among a PMOS transistor and an NMOS transistor forming the inverter, an input of which is the data input line DIN and an output of which is the inverted data input line DINB in the data input control unit 630. Since the PMOS transistors are formed in the third active region 1030, the conductive well corresponding to the third active region 1010 may be an N type well.

The PMOS transistor P1 and the NMOS transistor N1 may be aligned in the Y direction, and the PMOS transistor INVP and the NMOS transistor INVN may be aligned in the Y direction. The first active region 1010 and the third active region 1030 may be coupled with each other by metal lines 1044 and 1045 formed in the Y direction to form the first storage node SN1 and the output node of the inverter.

According to the layout shown in FIG. 10, since the transistors forming the latch circuit 510 shown in FIG. 6 may share as many drain/source junctions as possible, the occupied area of the latch circuit 510 may be minimized. Also, since it is possible to keep the first storage node SN1 apart from the third storage node SN3 and to keep the second storage node SN2 apart from the fourth storage node SN4, wherein the two storage nodes may avoid being simultaneously affected by cosmic rays, latch circuit 510 resistance to soft errors may increase.

In accordance with the embodiments of the present invention, latch circuits and semiconductor devices may have improved resistance to soft errors.

While the present invention has been described with respect to specific embodiments, the embodiments are not intended to be restrictive, but rather descriptive. Further, it is noted that the present invention may be achieved in various ways through substitution, change, and modification, by those skilled in the art without departing from the scope of the present invention as defined by the following claims.

What is claimed is:

1. A latch circuit, comprising:
first to N^{th} storage nodes, where N is an even number equal to or greater than 4;
first to N^{th} pairs of transistors, each of which includes a PMOS transistor and an NMOS transistor coupled in series with each other through a corresponding storage node among the first to N^{th} storage nodes, wherein each of the first to N^{th} storage nodes is coupled with a gate of the NMOS transistor included in a previous one of the pairs of transistors and a gate of the PMOS transistor included in a next one of the pairs of transistors; and
an initialization block suitable for initializing voltages of two or more nodes among the first to N^{th} storage nodes to a first level in response to an initialization signal.

2. The latch circuit of claim 1, wherein the initialization block initializes odd-numbered storage nodes, among the first to N^{th} storage nodes, to the first level in response to the initialization signal.

3. The latch circuit of claim 1, wherein the initialization block initializes even-numbered storage nodes among the first to N^{th} storage nodes to the first level in response to the initialization signal.

4. The latch circuit of claim 1, further comprising a data input control block suitable for transmitting data of a data input line to two or more nodes among the first to N^{th} storage nodes in response to a selection signal.

5. The latch circuit of claim 4, wherein a data output line is coupled with one among the first to N^{th} storage nodes.

6. The latch circuit of claim 5, wherein the data input line is shared by two or more latch circuits, and the data output line exclusively corresponds to a latch circuit.

7. A semiconductor device, comprising:
a non-volatile memory circuit;
a data bus suitable for transmitting data outputted from the non-volatile memory circuit;
a selection signal generation block suitable for generating a plurality of selection signals; and
a plurality of latch sets, each of which is enabled in response to a corresponding selection signal, among the selection signals, and stores the data transmitted through the data bus, and includes a plurality of latch circuits,
wherein each of the latch circuits includes:
first to N^{th} storage nodes, where N is an even number equal to or greater than 4;
first to N^{th} pairs of transistors, each of which includes a PMOS transistor and an NMOS transistor coupled in series with each other through a corresponding storage node among the first to N^{th} storage nodes, wherein each of the first to N^{th} storage nodes is coupled with a gate of the NMOS transistor included in a previous one of the pairs of transistors and a gate of the PMOS transistor included in a next one of the pairs of transistors;
an initialization block suitable for initializing voltages of two or more nodes among the first to N^{th} storage nodes to a first level in response to an initialization signal; and
a data input control block suitable for transmitting data of a corresponding line in the data bus to two or more storage nodes, among the first to N^{th} storage nodes, in response to a corresponding selection signal among the selection signals.

8. The semiconductor device of claim 7, wherein the selection signal generation block sequentially enables the selection signals whenever a clock is enabled.

9. The semiconductor device of claim 7,
wherein the semiconductor device is a memory device suitable for performing a repair operation to a failed memory cell included therein by using the data stored in the latch sets, and
wherein the non-volatile memory circuit stores repair data for the repair operation.

10. The semiconductor device of claim 9, further comprising a plurality of data output lines, each of which is coupled with one among the first to N^{th} storage nodes of each of the latch circuits and transfers data from one among the first to N^{th} storage nodes of each of the latch circuits to a repair circuit suitable for performing the repair operation.

11. The semiconductor device of claim 7, wherein a boot-up operation in which the non-volatile memory circuit transmits data stored therein to the latch circuits after the initialization block initializes the voltages of two or more nodes, among the first to N^{th} storage nodes, to the first level in response to the initialization signal.

12. The semiconductor device of claim 7, wherein the initialization block initializes odd-numbered storage nodes among the first to N^{th} storage nodes to the first level in response to the initialization signal.

13. The semiconductor device of claim 7, wherein the initialization block initializes even-numbered storage nodes, among the first to N^{th} storage nodes, to the first level in response to the initialization signal.

14. A latch circuit, comprising:
a first inverter including a first storage node as an input node and a second storage node as an output node;
a second inverter including the second storage node as an input node and the first storage node as an output node;
a first transistor coupled with the first storage node at its drain and source, and coupled with the second storage node at its gate; and
a second transistor coupled with the second storage node at its drain and source, and coupled with the first storage node at its gate.

15. The latch circuit of claim 14, wherein the first transistor and the second transistor are PMOS transistors.

16. The latch circuit of claim 14, further comprising an initialization block suitable for initializing a voltage of one among the first and second storage nodes to a first level in response to an initialization signal.

17. The latch circuit of claim 14, further comprising a data input control block suitable for transmitting input data to one or more among the first and second storage nodes in response to a selection signal.

18. The latch circuit of claim 14, further comprising a data output block suitable for outputting data stored in one among the first and second storage nodes.

19. A semiconductor device, comprising:
a non-volatile memory circuit;
a data bus suitable for transmitting data outputted from the non-volatile memory circuit;
a selection signal generation block suitable for generating a plurality of selection signals; and
a plurality of latch sets, each of which is enabled in response to a corresponding selection signal, among the selection signals, and stores the data transmitted through the data bus, and includes a plurality of latch circuits,
wherein each of the latch circuits includes:
a first inverter including a first storage node as an input node and a second storage node as an output node;
a second inverter including the second storage node as an input node and the first storage node as an output node;
a first transistor coupled with the first storage node at its drain and source, and coupled with the second storage node at its gate;
a second transistor coupled with the second storage node at its drain and source, and coupled with the first storage node at its gate;
a data input control block suitable for transferring data from the data bus to one or more among the first and second storage nodes in response to a corresponding selection signal among the selection signals.

20. The semiconductor device of claim 19, wherein the first transistor and the second transistor are PMOS transistors.

21. A latch circuit, comprising:
a first PMOS transistor including a source coupled with a power source voltage node, a drain coupled with a first storage node, and a gate coupled with a fourth storage node;
a first NMOS transistor including a drain coupled with the first storage node, a source coupled with a ground voltage node, and a gate coupled with a second storage node;
a second PMOS transistor including a source coupled with the power source voltage node, a drain coupled with a second storage node, and a gate coupled with a first storage node;
a second NMOS transistor including a drain coupled with the second storage node, a source coupled with the ground voltage node, and a gate coupled with a third storage node;
a third PMOS transistor including a source coupled with the power source voltage node, a drain coupled with a third storage node, and a gate coupled with the second storage node;
a third NMOS transistor including a drain coupled with the third storage node, a source coupled with the ground voltage node, and a gate coupled with the fourth storage node;
a fourth PMOS transistor including a source coupled with the power source voltage node, a drain coupled with the fourth storage node, and a gate coupled with the third storage node;
a fourth NMOS transistor including a drain coupled with the fourth storage node, and a source coupled with the ground voltage node, and a gate coupled with the first storage node;
a fifth PMOS transistor suitable for initializing the fourth storage node to a first level in response to an initialization signal;
a sixth PMOS transistor suitable for initializing the second storage node to the first level in response to the initialization signal;
a fifth NMOS transistor suitable for transmitting data of an inverted data input line to the second storage node in response to a selection signal;
a sixth NMOS transistor suitable for transmitting data of a data input line to the third storage node in response to the selection signal;
a seventh NMOS transistor suitable for transmitting the data of the inverted data input line to the fourth storage node in response to the selection signal; and
an eighth NMOS transistor suitable for transmitting the data of the data input line to the first storage node in response to the selection signal.

22. The latch circuit of claim 21, wherein the first to eighth NMOS transistors are arranged in order of the fourth NMOS transistor, the seventh NMOS transistor, the fifth NMOS transistor, the second NMOS transistor, the third NMOS transistor, the sixth NMOS transistor, the eighth NMOS transistor and the first NMOS transistor, in a first direction in a first active region stretched in the first direction.

23. The latch circuit of claim 22, wherein the second to sixth PMOS transistors are arranged in order of the fourth PMOS transistor, the fifth PMOS transistor, the sixth PMOS transistor, the second PMOS transistor and the third PMOS transistor in the first direction in a second active region stretched in the first direction.

24. The latch circuit of claim 23,
further comprising an inverter including the data input line as an input line and the inverted data input line as an output line,
wherein the inverter includes a seventh PMOS transistor and a ninth NMOS transistor

25. The latch circuit of claim 24, wherein the first PMOS transistor and the seventh PMOS transistor are arranged in order of the first PMOS transistor and the seventh PMOS transistor, in the first direction in a third active region stretched in the first direction.

26. The latch circuit of claim 25, wherein the ninth NMOS transistor is arranged at the end of the order in the first direction in the first active region.

27. The latch circuit of claim 26,
wherein the drain of the fourth PMOS transistor in the second active region and the drain of the fourth NMOS transistor in the first active region are aligned in a second direction perpendicular to the first direction, and the drain of the fourth PMOS transistor and the drain of the fourth NMOS transistor are coupled with each other through a first metal line, and
wherein the drain of the second PMOS transistor in the second active region and the drain of the second NMOS transistor in the first active region are aligned in the second direction, and the drain of the second PMOS transistor and the drain of the second NMOS transistor are coupled with each other through a second metal line,
wherein the drain of the third PMOS transistor in the second active region and the drain of the third NMOS transistor in the first active region are aligned in the second direction, and the drain of the third PMOS transistor and the drain of the third NMOS transistor are coupled with each other through a third metal line, and
wherein the drain of the first PMOS transistor in the third active region and the drain of the first NMOS transistor in the first active region are aligned in the second direction, and the drain of the first PMOS transistor and the drain of the first NMOS transistor are coupled with each other through a fourth metal line.

28. The latch circuit of claim 27, wherein the drain of the seventh PMOS transistor in the third active region and the drain of the ninth NMOS transistor in the first active region are aligned in the 10 second direction, and the drain of the seventh PMOS transistor and the drain of the ninth NMOS transistor are coupled with each other through a fifth metal line.

29. The latch circuit of claim 28,
wherein a well corresponding to the first active region is a P-type well,
wherein a well corresponding to the second active region is an N-type well, and
wherein a well corresponding to the third active region is an N-type well.
